(19) United States
(12) Patent Application Publication
(10) Pub. No.: US 2005/0098709 A1
(43) Pub. Date: May 12, 2005

(54) Image sensor package

(76) Inventors: Jackson Hsieh, Hsinchu Hsien (TW); Jichen Wu, Hsinchu Hsien (TW); Eric Chang, Hsinchu Hsien (TW); Kenny Chen, Hsinchu Hsien (TW)

Correspondence Address: PRO-TECHTOR INTERNATIONAL, 20775 Norada Court, Saratoga, CA, 95070-3018, US

(21) Appl. No.: 10/705,376

(22) Filed: Nov. 10, 2003

(51) Int. Cl. H01L 27/00

(52) U.S. Cl. 250/208.1

(57) ABSTRACT

An image sensor package includes plural lower metal sheets, plural upper metal sheets stacked on the lower metal sheets, and an encapsulant for encapsulating the lower and upper metal sheets. Wherein the upper metal sheets are shorter than that of the lower metal sheets, so the upper surface of the lower metal sheets are exposed from the encapsulant. A photosensitive chip arranged within the chamber, plural wires are for electrically connecting the chip to the upper surfaces of the lower metal sheets, and a transparent layer arranged on the frame layer to cover the chip.

### BACKGROUND OF THE INVENTION

1. Field of the Invention

The invention relates to an image sensor module package, and more particularly to an image sensor with increased product reliability and facilitated manufacturing processes.

2. Description of the Related Art

Referring to FIG. 1, which is a cross-sectional view showing an image sensor package. The image sensor includes a plurality of lower metal sheets10 arranged in an array, each of the lower metal sheets10 having an upper surface26 and a lower surface28. A plurality of upper metal sheets12 arranged in an array, each of the upper metal sheets12 having an upper surface38 and a lower surface40, the lower surfaces40 of the upper metal sheets12 being stacked on the upper surfaces26of the lower metal sheets10. An encapsulant14 is for encapsulating the lower metal sheets10 and the upper metal sheets12. Wherein the upper surfaces38 of the upper metal sheets12 are exposed from the encapsulant14. The lower surfaces28 of the lower metal sheets10 are exposed from the encapsulant14 and electrically connected to the printed circuit board, and the encapsulant14 is formed with a frame layer16 around the upper surfaces38 of the upper metal sheets12 to define a chamber42 together with the upper metal sheets12. A photosensitive chip18 arranged within the chamber. Wires20 are for electrically connecting the photosensitive chip18 to the upper surfaces38 of the upper metal sheets12. A transparent layer22 arranged on the frame layer16 of the encapsulant14 to cover the photosensitive chip18.

The above-mentioned the patent has some advantages, but it has following drawbacks.

1.Since the wires 20 are electrically connected the chip18 to the upper surface38 of the upper metal sheets12 for transmitting signals from the chip18 to the lower metal sheets12. Thus, the upper metals12 and the lower metal sheets10 much be tight stacked.

### SUMMARY OF THE INVENTION

An object of the invention is to provide an image sensor package with improved package reliability.

Still another object of the invention is to provide an image sensor package, wherein the wire bonding process may be easily performed and the product yield may be increased.

To achieve the above-mentioned objects, the invention includes a plurality of lower metal sheets arranged in an array, each of the lower metal sheets have an upper surface and a lower surface. A plurality of upper metal sheets arranged in an array, each of the upper metal sheets has an upper surface and a lower surface. The upper metal sheets are shorter than that of the lower metal sheet. The lower surfaces of the upper metal sheets being stacked on the upper surfaces of the lower metal sheets, so a part of the upper surface of the lower metals sheets are exposed from the upper metal sheets. An encapsulant is encapsulated the lower metal sheets and the upper metal sheets. Wherein the upper surfaces of the lower metal sheets are exposed from the encapsulant. The lower surfaces of the lower metal sheets are exposed from the encapsulant and electrically connected to the printed circuit board, and the encapsulant is formed with a frame layer around the upper surfaces of the upper metal sheets to define a chamber together with the upper metal sheets. A photosensitive chip is arranged within the chamber. A plurality of wires are electrically connected the photosensitive chip to the upper surfaces of the lower metal sheets. A transparent layer is arranged on the frame layer of the encapsulant to cover the photosensitive chip.

### BRIEF DESCRIPTION OF THE DRAWINGS

FIG. 1 is a cross-sectional view showing an image sensor disclosed in a commonly-assigned, copending U.S. patent application Ser. No. ______, filed on May 15, 2002.

FIG. 2 is a cross-sectional view showing an image sensor package of the present invention.

FIG. 3 is a schematic view showing an image sensor package of the invention.

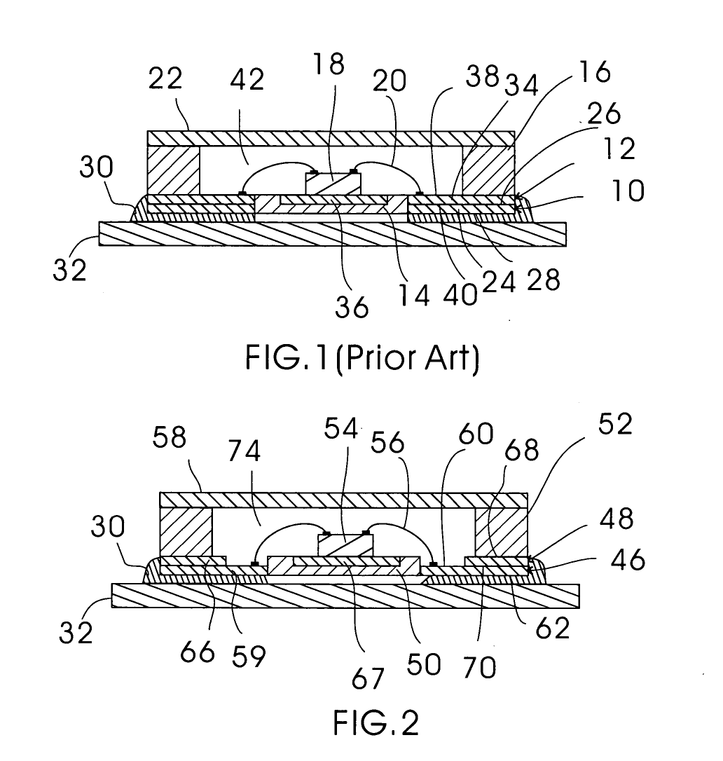

### DETAILED DESCRIPTION OF THE INVENTION

Referring to FIG. 2,an image sensor of the invention includes a plurality of lower metal sheets 46 arranged in an array, a plurality of upper metal sheets 48arranged in an array, an encapsulant 50, a frame layer52, a photosensitive chip 54, a plurality of wires 56, and a transparent layer 58.

Each lower metal sheet 46 has an upper surface 60 and a lower surface 62.

A plurality of upper metal sheets48 is arranged in an array, each of the upper metal sheets48 have an upper surface68 and a lower surface70. The upper metal sheets48 are shorter than that of the lower metal sheet46. The lower surfaces70 of the upper metal sheets48 are stacked on the upper surfaces60 of the lower metal sheets46, so part of the upper surface68 of the lower metal sheets48 are exposed from the upper metal sheets46.

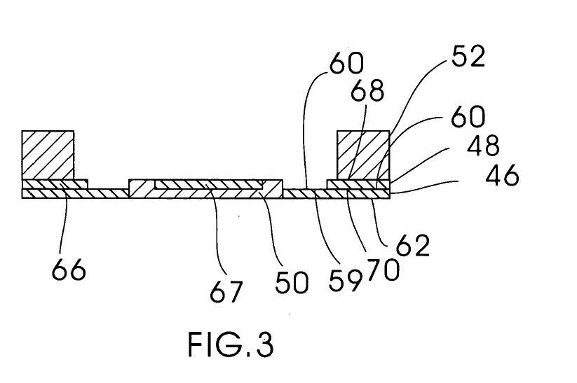

Please referring to FIG. 3, the encapsulant 54 is encapsulated the lower metal sheets 46and the upper metal sheets 48 via integrated mold. Wherein the upper surfaces60 of the lower metal sheets46 are exposed from the encapsulant54. The lower surfaces62 of the lower metal sheets46 are exposed from the encapsulant54 and electrically connected to the printed circuit board32 via solder30. The encapsulant is formed with a frame layer52 around the upper surfaces68 of the upper metal sheets48 to define a chamber74 together with the upper metal sheets48.

The photosensitive chip 54 is arranged on the middle board 67 and located within the chamber 74.

The plurality of wires 56 are electrically connected the photosensitive chip 54 to the upper surfaces 60 of the upper metal sheets 46 so as to transfer signals from the photosensitive chip 54 to the lower metal sheets 46.

The transparent layer 58 is a piece of transparent glass arranged on the frame layer 52 of the encapsulant 50 to cover the photosensitive chip 54. Thus, the photosensitive chip 54 may receive optical signals passing through the transparent layer 58.

The invention has the following advantages.
1. Since the combination of the upper and lower metal sheets 48 and 46 is thicker, the solder 30 may climb to the upper metal sheets 48 from the lower metal sheets 46 during the SMT process for mounting the image sensor to the printed circuit board 32. Therefore, the package body can be mounted to the printed circuit board 32 with great stability.
2. Since the wires56 are electrically connected the chip54 to the upper surface60 of the lower metal sheets46, no through the upper metal sheets48, so as to the signal from the chip54 may effectively transmit to the printed circuit board32.

While the invention has been described by way of examples and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

1. An image sensor package to be electrically connected to a printed circuit board, the image sensor comprising:
a plurality of lower metal sheets arranged in an array, each of the lower metal sheets having an upper surface and a lower surface;
a plurality of upper metal sheets arranged in an array, each of the upper metal sheets having an upper surface and a lower surface, wherein the upper metal sheets are shorter than that of the lower metal sheet, the lower surfaces of the upper metal sheets being stacked on the upper surfaces of the lower metal sheets, so as to part of the upper surface of the lower metals sheets are exposed from the upper metal sheets;
an encapsulant for encapsulating the lower metal sheets and the upper metal sheets, wherein the upper surfaces of the lower metal sheets are exposed from the encapsulant, the lower surfaces of the lower metal sheets are exposed from the encapsulant and electrically connected to the printed circuit board, and the encapsulant is formed with a frame layer around the upper surfaces of the upper metal sheets to define a chamber together with the upper metal sheets;
a photosensitive chip arranged within the chamber;
a plurality of wires for electrically connecting the photosensitive chip to the upper surfaces of the lower metal sheets;
a transparent layer arranged on the frame layer of the encapsulant to cover the photosensitive chip.

2. The image sensor package according to claim 1, wherein the encapsulant is made of industrial plastic material, and the encapsulant and the frame layer are integrally formed.

3. The image sensor package according to claim 1, wherein the transparent layer is a piece of transparent glass.
